(19) United States
(12) Patent Application Publication
(10) Pub. No.: US 2016/0267975 A1
(43) Pub. Date: Sep. 15, 2016

(54) SEMICONDUCTOR MEMORY

(71) Applicant: Renesas Electronics Corporation, Tokyo (JP)

(72) Inventors: Kiyoshi TAKEUCHI, Tokyo (JP); Takashi Hase, Tokyo (JP)

(21) Appl. No.: 14/964,383

(22) Filed: Dec. 9, 2015

(30) Foreign Application Priority Data
Mar. 9, 2015 (JP) 2015-045999

(51) Int. Cl. G11C 13/00

(52) U.S. Cl. CPC G11C 13/0069; G11C 13/004; G11C 13/0064

(57) ABSTRACT

A semiconductor memory includes a memory cell including a resistance change element and a control circuit configured to perform OFF-write processing of applying an OFF-write pulse to the memory cell for switching the state of the memory cell to a high-resistive state where a resistance value of the resistance change element is at least a first reference value and ON-write processing of applying an ON-write pulse to the memory cell for switching the state of the memory cell to a low-resistive state where the resistance value is less than a second reference value. The control circuit performs the OFF-write processing by applying an auxiliary pulse which is smaller than the OFF-write pulse in voltage amplitude to the memory cell one or more time(s) after having applied the OFF-write pulse to the memory cell.

### CROSS-REFERENCE TO RELATED APPLICATIONS

The disclosure of Japanese Patent Application No. 2015-045999 filed on Mar. 9, 2015 including the specification, drawings and abstract is incorporated herein by reference in its entirety.

### BACKGROUND

The present invention relates to a memory and, in particular, relates to a technology which is applicable to a semiconductor memory using a resistance change element.

In Japanese Patent No. 4875624, a method of performing resistance-lowering (crystallization) writing at a high speed by applying first a high voltage and then a low voltage to a phase-change memory element is described. In addition, in each of Japanese Patent Nos. 5133471 and 4838399, a method of applying a weak and reversely directed pulse before applying a main write pulse and thereby improving stability of write data in a bipolar operation type ReRAM (a resistance change type memory) is described.

### SUMMARY

In Japanese Patent No. 4875624, although the phase change memory is described, a method of improving the characteristics of the ReRAM is not described. In addition, the behavior of the resistive state which is peculiar to the ReRAM is not solved by the invention described in Japanese Patent No. 4875624. In addition, although it is possible to stabilize a write resistance of the ReRAM by the methods described in Japanese Patent Nos. 5133471 and 4838399, the effect of resistance stabilization which is brought about by these methods is insufficient and therefore a method of more increasing the resistance in a high-resistive state is being demanded.

Other subject matters and novel features of the present invention will become apparent from the description of the present specification and appended drawings.

A semiconductor memory according to one embodiment of the present invention includes a memory cell which includes a resistance change element and a control circuit configured to perform first write processing of applying a first write pulse to the memory cell in order to switch the state of the memory cell to a first resistive state where a resistance value of the resistance change element is at least a first reference value and second write processing of applying a second write pulse to the memory cell in order to switch the state of the memory cell to a second resistive state where the resistance value of the resistance change element is less than a second reference value. The control circuit performs the first write processing by applying a first auxiliary pulse which is smaller than the first write pulse in voltage amplitude one or more time(s) after having applied the first write pulse to the memory cell.

According to the above-mentioned one embodiment of the present invention, it is possible to stabilize a write state relative to a resistance element of the ReRAM and thereby to improve characteristics of the ReRAM.

### BRIEF DESCRIPTION OF THE DRAWINGS

FIG. 1 is a schematic diagram illustrating one configurational example of a resistance change element to be used in a bipolar type ReRAM according to a first embodiment of the present invention.

FIG. 2 is a schematic diagram illustrating one configurational example of a memory cell.

FIG. 3 is a schematic diagram illustrating one configurational example of a memory cell array in the ReRAM.

FIG. 4 is a diagram illustrating one waveform example of a voltage to be generally applied when performing writing for switching the memory cell to an OFF state.

FIG. 5A is a diagram illustrating one example of one waveform of a voltage to be applied when performing writing for switching the memory cell to the OFF state in the first embodiment of the present invention.

FIG. 5B is a diagram illustrating another example of the waveform of the voltage to be applied when performing writing for switching the memory cell to the OFF state in the first embodiment of the present invention.

FIG. 6A is a schematic diagram illustrating one example of an operation of the resistance change element.

FIG. 6B is a schematic diagram illustrating another example of the operation of the resistance change element.

FIG. 7 is a schematic diagram illustrating a further another example of the operation of the resistance change element.

FIG. 8A is a diagram illustrating one example of another waveform of the voltage to be applied when performing writing for switching the memory cell to the OFF state in the first embodiment of the present invention.

FIG. 8B is a diagram illustrating another example of the waveform of the voltage to be applied when performing writing for switching the memory cell to the OFF state in the first embodiment of the present invention.

FIG. 9A is a diagram illustrating one example of a waveform of a voltage to be applied when performing writing for switching the memory cell to the OFF state in a second embodiment of the present invention.

FIG. 9B is a diagram illustrating another example of the waveform of the voltage to be applied when performing writing for switching the memory cell to the OFF state in the second embodiment of the present invention.

FIG. 10 is a flowchart illustrating one example of a procedure of writing for switching the memory cell to the OFF state in the second embodiment of the present invention.

FIG. 11 is a diagram illustrating one example of a waveform of a voltage to be applied when performing writing for switching the memory cell to the OFF state in a third embodiment of the present invention.

FIG. 12 is a flowchart illustrating one example of a procedure of writing for switching the memory cell to the OFF state in the third embodiment of the present invention.

FIG. 13 is a diagram illustrating one example of a waveform of a voltage to be applied when performing writing for switching the memory cell to the OFF state in a fourth embodiment of the present invention.

FIG. 14 is a flowchart illustrating one example of a procedure of writing for switching the memory cell to the OFF state in the fourth embodiment of the present invention.

FIG. 15 is a flowchart illustrating another example of the procedure of writing for switching the memory cell to the OFF state in the fourth embodiment of the present invention.

FIG. 16 is a diagram illustrating one example of a waveform of a voltage to be applied when performing a verifying operation on a main pulse in a fifth embodiment of the present invention.

FIG. 17 is a flowchart illustrating one example of a procedure of writing when performing the verifying operation on the main pulse in the fifth embodiment of the present invention.

FIG. 18 is a diagram illustrating one example of a waveform obtained when an auxiliary pulse is applied prior to performance of ON writing in a sixth embodiment of the present invention.

FIG. 19 is a schematic diagram illustrating one configurational example of a memory cell of a cross point type ReRAM according to a seventh embodiment of the present invention.

FIG. 20 is a schematic diagram illustrating one configurational example of a memory cell array in the cross point type ReRAM according to the seventh embodiment of the present invention.

### DETAILED DESCRIPTION

In the following, preferred embodiments of the present invention will be described in detail with reference to the accompanying drawings. Incidentally, the same numerals or symbols are assigned to the same parts in principle in all of the drawings which are appended in order to describe the embodiments of the present invention and repetitive description thereof is omitted.

In an existing ReRAM, there are cases where a resistance (an OFF resistance) when a resistance element is in the high-resistive state (the OFF state) is not sufficiently increased. In regard to this point, the inventors and others of the present invention have found that it is possible to increase the OFF resistance by applying an auxiliary pulse which is configured by an OFF pulse or an ON pulse which is weaker than a write pulse one or more time(s) in addition to the write pulse to be applied for switching to the OFF state.

Accordingly, in the following embodiments, in a semiconductor memory which is configured by a bipolar type ReRAM, the OFF resistance is increased so as to improve the characteristics of the ReRAM by controlling so as to apply the auxiliary pulse which is weaker than the write pulse as the main pulse in the OFF state. Incidentally, in the following, although description will be made on the assumption that the bipolar type ReRAM that the polarity of the write pulse to be applied is made different depending on whether the state is switched to the ON state or the Off state is used, basically, it is also possible to apply the same mechanism as the above even to a unipolar type ReRAM which performs writing with pulses of the same polarity.

### FIRST EMBODIMENT

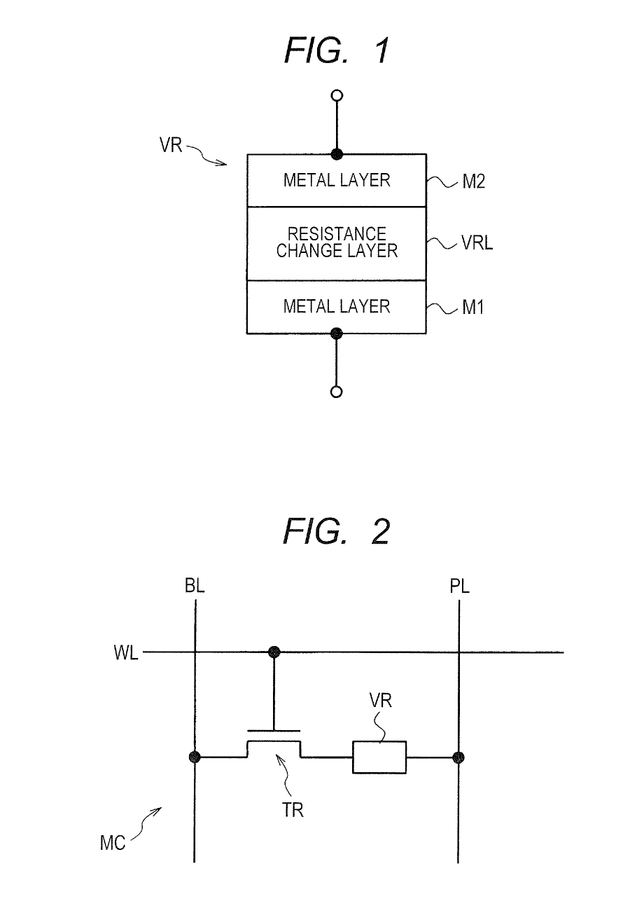

FIG. 1 is a schematic diagram illustrating one configurational example of a resistance change element to be used in the bipolar type ReRAM according to the first embodiment of the present invention. A resistance change element VR has a configuration that a resistance change layer VRL is sandwiched between a metal layer M1 and a metal layer M2 and the metal layer M1 and the metal layer M2 respectively configure a first electrode and a second electrode. It is possible to change the resistance change layer VRL to a low resistive state (the ON state) by applying a positive voltage to the metal layer M2 with the metal layer M1 being set as a reference and it is possible to change the resistance change layer VRL to the high resistive state (the OFF state) by applying the positive voltage to the metal layer M1 with the metal layer M2 being set as the reference. One-bit information is stored by making the ON state and the OFF state respectively correspond to “0” and “1” or to “1” and “0”.

The resistance change layer VRL is made of, for example, a metal oxide (for example, a tantalum oxide, a titanium oxide, a zirconium oxide, a hafnium oxide and so forth). In this case, the resistance change layer VRL may be either a single layer film or a laminated film. When the resistance change layer VRL is configured by the laminated film, the resistance change film VRL may be either a laminated film that, for example, respective layers are mutually different in combination of the kinds of chemical elements or a laminated film that the respective layers are the same as one another in combination of the kinds of the chemical elements. In this case, oxygen composition ratios of the respective layers of the laminated film are mutually different. Incidentally, a film thickness of the resistance change layer VRL is, for example, at least about 1.5 nm and not more than about 30 nm. The metal layer M1 and the metal layer M2 are each made of, for example, ruthenium, titanium nitrogen, tantalum, tantalum nitrogen, tungsten, palladium, platinum and so forth.

FIG. 2 is a schematic diagram illustrating one configurational example of a memory cell in the ReRAM. A memory cell MC may be configured by combining the resistance change element VR illustrated in FIG. 1 with a selection transistor TR which is configured by a MOS (Metal-Oxide Semiconductor) transistor. The selection transistor TR is a selection transistor adapted to control whether a potential difference between a bit line BL and a plate line PL is to be applied to the resistance change element VR or blocked.

The resistance change element VR is coupled to the plate line PL at one terminal and is coupled to the bit line BL at the other terminal via the selection transistor TR. In addition, a gate of the selection transistor TR is coupled to a word line WL. It is possible to switch the polarity of the voltage to be applied to the resistance change element VR depending on which one of the potentials of the bit line BL and the plate line PL is set higher than the other.

Although there is no particular limitation on which metal layer, the metal layer M1 or the metal layer M2, is to be coupled to the bit line BL, in the following, description will be made on the assumption that the metal layer M1 is coupled with the bit line BL. In addition, there is no limitation on which type of transistor, the N channel type or the P channel type, the selection transistor TR is, in the following, description will be made on the assumption that the selection transistor TR is the N channel type transistor that a source and a drain thereof are conducted by applying the positive voltage to a gate thereof. Incidentally, when the selection transistor TR is the P channel type transistor, the source and the drain are conducted by applying a negative voltage to the gate thereof.

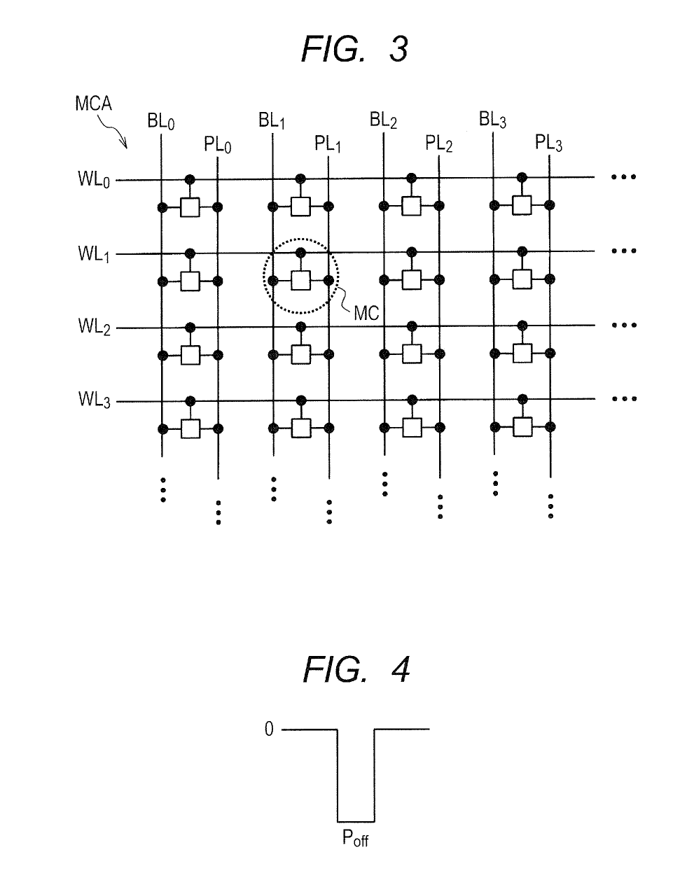

FIG. 3 is a schematic diagram illustrating one configurational example of a memory cell array in the ReRAM. A memory cell array MCA may be configured by arranging the memory cells MC illustrated in FIG. 2 in a matrix. Although in the example of the memory cell array MCA illustrated in FIG. 3, the memory cell array MCA has a configuration having a 16-bit memory capacity configured by the memory cells MC which are arranged in the matrix of four rows×four columns, it is possible to implement a larger memory capacity by appropriately increasing the numbers of the rows and the columns of the array.

Each of the memory cells MC is coupled to each node between each of the word lines WL₀ to WL₃ and each of the bit lines BL₀ to BL₃ and to each node between each of the word lines WL₀ to WL₃ and each of the plate lines PL₀ to PL₃. Then, all of the word lines WL₀ to WL₃, the bit lines BL₀ to BL₃ and the plate lines PL₀ to PL₃ are respectively coupled to not illustrated control circuits on the periphery of the memory cell array MCA. For example, the word lines WL₀ to WL₃ are coupled to a not illustrated word line control circuit on the left side of the memory cell array MCA in the drawing. In addition, the bit lines BL₀ to BL₃ are coupled to a not illustrated bit line control circuit on the upper side of the memory cell array MCA in the drawing. Likewise, the plate lines PL₀ to PL₃ are coupled to a not illustrated plate line control circuit on the upper side of the memory cell array MCA in the drawing.

Each of the control circuits performs writing by appropriately applying a voltage to the corresponding line, that is, the word line WL, the bit line BL or the plate line PL and switching a desired memory cell MC to the high resistive state or the low resistive state. Otherwise, each of the control circuits performs reading by detecting a current which flows through the bit line BL or the plate line PL and determining whether the desired memory cell MC is in the high resistive state or the low resistive state.

For example, in writing for switching the memory cell MC which is circled with the dotted line to the ON state, the word line WL₁ and the plate line PL₁ may be set to high potentials and other word lines WL₀, WL₂ and WL₃, other plate lines PL₀, PL₂ and PL₃ and all of the bit lines BL₀ to BL₃ may be set to zero potentials. In contrast, in writing for switching the memory cell MC which is circled with the dotted lines to the OFF state, the word line WL₁ and the bit line BL₁ may be set to the high potentials and other word lines WL₀, WL₂ and WL₃, other bit lines BL₀, BL₂ and BL₃ and all of the plate lines PL₀ to PL₃ may be set to the zero potentials.

In addition, when performing reading by determining whether the memory cell MC which is circled with the dotted line is in the ON state or the OFF state, the word lines WL₀, WL₂ and WL₃ other than the word line WL₁, the plate lines PL₀, PL₂ and PL₃ other than the plate line PL₁ and all of the bit lines BL₀ to BL₃ are set to the zero potentials and the word line WL₁ is set to the high potential. Then, a voltage which is sufficiently lower than the voltage applied when writing is performed may be applied to the plate line PL₁ and thereby a current which flows through the bit line BL₁ or the plate line PL₁ may be detected.

In the above-mentioned operation, in each of the memory cells MC which have been coupled to the word lines other than the word line WL₁, the selection transistor TR is brought into a non-conductive state and the voltage is not applied to the resistance change element VR of the memory cell MC concerned. In addition, in each of the memory cells MC which have been coupled to the bit lines other than the bit line BL₁ and the plate lines other than the plate line PL₁, since the bit lines BL₀, BL₂ and BL₃ and the plate lines PL₀, PL₂ and PL₃ are set to the same potential, the voltage is not applied to the resistance change element VR of the memory cell MC concerned. Thereby, writing or reading is performed only on the memory cell MC which is circled with the dotted line. It is possible to perform writing and reading on other memory cells MC by the same technique.

FIG. 4 is a diagram illustrating one example of a waveform of a voltage to be generally applied when performing writing for switching the memory cell MC to the OFF state. In order to switch the resistance change element VR of the memory cell MC illustrated in FIG. 2 to the high resistive state (the OFF state), the voltage which is higher than the voltage to be applied to the plate line PL side is applied to the bit line BL side of the resistance change element VR. However, in general, the voltage is applied one time in a pulsed form (P_{off}) as illustrated in FIG. 4. For this purpose, for example, the potential on the bit line BL side may be set higher than the potential on the plate line PL side and in this state the potential on the word line WL side may be increased so as to make the selection transistor TR conductive for a predetermined period of time. As an alternative, the potential on the word line WL side may be increased so as to make the selection transistor TR conductive and in this state a pulsed voltage for setting the bit line BL side to a positive potential may be applied between the bit line BL and the plate line PL.

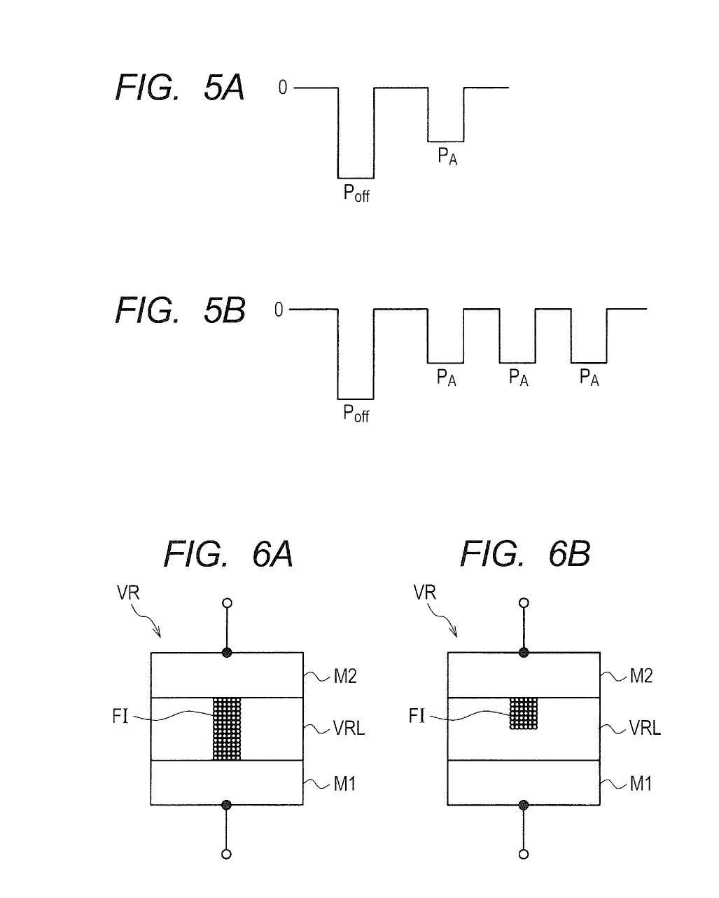

FIG. 5A and FIG. 5B each are a diagram illustrating one example of a waveform of a voltage to be applied when performing writing for switching the memory cell MC to the OFF state in the first embodiment. In the examples in FIG. 5A and FIG. 5B, the write pulse P_{off} for switching the memory cell MC to the OFF state such as that illustrated in FIG. 4 is applied and, in addition to the write pulse P_{off}, an auxiliary pulse P_{A} which is smaller than the write pulse P_{off} in voltage amplitude and is the same as the write pulse P_{off} in polarity is subsequently applied. Although in the example in FIG. 5A, the number of times of applying the auxiliary pulse P_{A} is “1”, the number of times may be a plurality of times amounting to “2” or more numerals as desired as illustrated in FIG. 5B. Although in the examples in FIG. 5A and FIG. 5B, the auxiliary pulse P_{A} has a pulse width which is the same as that of the write pulse P_{off}, the auxiliary pulse P_{A} may have the pulse width which is different from that of the write pulse P_{off}.

It is possible to more increase the OFF resistance than ever by applying the auxiliary pulse P_{A} in addition to application of the write pulse P_{off} (hereinafter, referred to as a “main pulse” as the case may be) as described above. Thereby, it is possible to more increase the ratio of the ON resistance to the OFF resistance so as to more facilitate reading to be performed on the memory cell MC and thereby it is possible to improve the characteristics of the semiconductor memory according to the first embodiment as the memory.

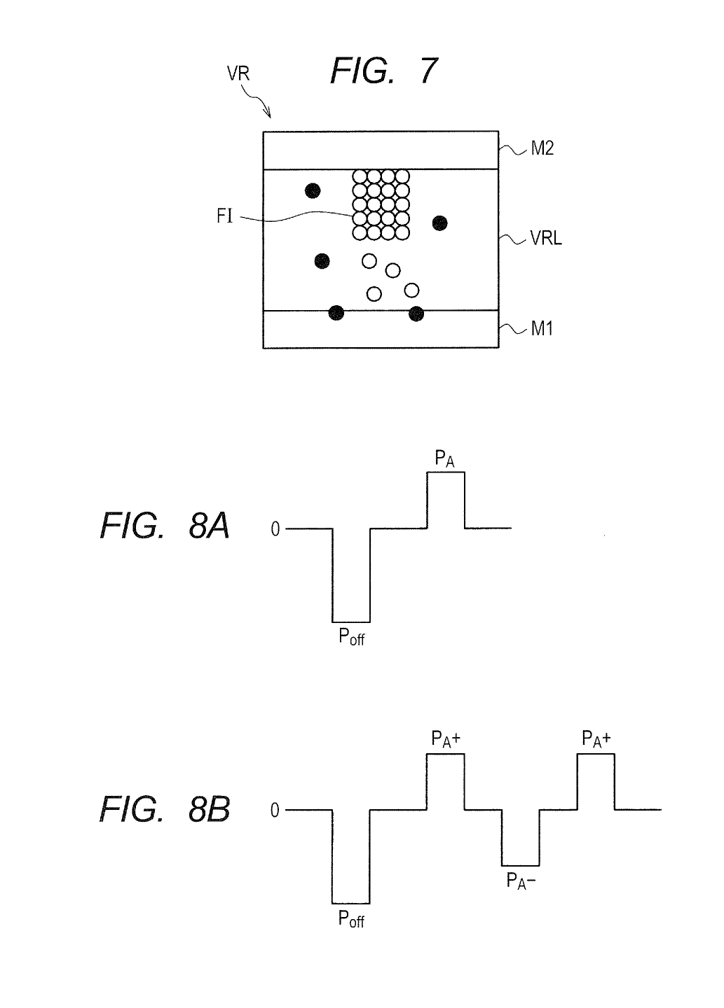

Possible reasons for obtaining the advantageous effect of increasing the OFF resistance as mentioned above will be described as follows. FIG. 6A, FIG. 6B and FIG. 7 each are a schematic diagram illustrating one example of an operation of the resistance change element VR. As illustrated in FIG. 6A, when a conductive filament F1 formed in the resistance change layer VR comes into a state of linking together the metal layer M1 and the metal layer M2, the resistance change element VR is switched to the low resistive state (the ON state). On the other hand, as illustrated in FIG. 6B, when the conductive filament F1 comes into a state of not fully linking together the metal layer M1 and the metal layer M2 (a gap is present between the metal layers M1 and M2), the resistance change element VR is switched to the high resistive state (the OFF state).

FIG. 7 is a schematic and enlarged diagram illustrating one example of main part relevant to the conductive filament F1 in FIG. 6B. In FIG. 7, a white circle indicates a defect (an oxygen vacancy) that oxygen is deficient and a black circle indicates oxygen. The conductive filament F1 is formed by gathering together the oxygen vacancies highly densely.

Changing from the low resistive state illustrated in FIG. 6A to the high resistive state illustrated in FIG. 6B (resistance increasing) is implemented by extinguishing the oxygen vacancies by combining them with surrounding oxygen in a partial region of the conductive filament F1 by applying the write pulse P_{off} such as that illustrated in FIG. 4. However, it is difficult to extinguish all of the oxygen vacancies and some oxygen vacancies remain, for example, in a gap part and so forth between the metal layer M1 and the conductive filament F1 as illustrated in the example in FIG. 7. Such a disadvantage occurs that the resistance between the metal layer M1 and the metal layer M2 is not sufficiently increased because electrical conduction via the residual oxygen vacancies as mentioned above still remains.

In such a situation as mentioned above, in the first embodiment, the auxiliary pulse P_{A} such as that illustrated in FIG. 5 is applied to the resistance change element VR as mentioned above. Thereby, an electric field directing from the metal layer M1 toward the metal layer M2 is generated in the resistance change layer VRL and oxygen which is present closer to the metal layer M2 side (on the upper side in the drawing) than to the gap part is drawn toward the metal layer M1 side (the lower side in the drawing) because oxygen is negatively charged. Consequently, a probability that the drawn oxygen meets the residual oxygen vacancies is increased and combination of oxygen with the residual oxygen vacancies and extinction of the oxygen vacancies are promoted and the resistance between the metal layer M1 and the metal layer M2 is increased.

Incidentally, if the voltage of the auxiliary pulse P_{A} to be applied is too large, generation of new oxygen vacancies will be rather promoted by the electric field and an adverse effect will be induced, and switching from the OFF state to the ON state will occur depending on the situation. Accordingly, the amplitude of the auxiliary pulse P_{A} is suppressed to be smaller than the amplitude of the write pulse P_{off} (the main pulse).

FIG. 8A and FIG. 8B each are a diagram illustrating one example of another waveform of the voltage to be applied when performing writing for switching the memory cell MC to the OFF state in the first embodiment. As illustrated in FIG. 8A, even when the polarity of the auxiliary pulse P_{A} is reverse to the polarity of the main pulse, the same advantageous effects as above are obtained. In this case, in the example in FIG. 7, the oxygen which is present closer to the metal layer M1 side (the lower side in the drawing) than to the conductive filament F1 is drawn toward the metal layer M2 side (the upper side in the drawing) and the provability that the oxygen meets the residual oxygen vacancies is increased.

As illustrated in FIG. 8B, it is also possible to combine an auxiliary pulse P_{A+} of a polarity which is reverse to the polarity of the main pulse with an auxiliary pulse P_{A-} of a polarity which is the same as the polarity of the main pulse. For example, as illustrated in FIG. 8B, oxygen is made to migrate up and down on the periphery of the residual oxygen vacancies by alternately applying the auxiliary pulses P_{A+} and P_{A-} which run in opposite directions. Thereby, it is possible to more effectively promote combination of oxygen with the residual oxygen vacancies and thereby it is possible to increase the advantageous effect of increasing the resistance. Incidentally, the patterns of applying the auxiliary pulses P_{A+} and P_{A-} are not limited to those illustrated in FIG. 8A and FIG. 8B. Since what pattern is optimum may be different depending on the feature of the resistance change element VR used, it is desirable to appropriately select the pattern.

As described above, according to the ReRAM of the first embodiment, it is possible to promote extinction of conductive defects (the oxygen vacancies) which still remain in the OFF state by applying the auxiliary pulse P_{A} which is weaker than the OFF write pulse P_{off} one or more time(s) in addition to application of the OFF write pulse P_{off}. Thereby, it is possible to increase the OFF resistance and to improve the characteristics of the ReRAM.

### SECOND EMBODIMENT

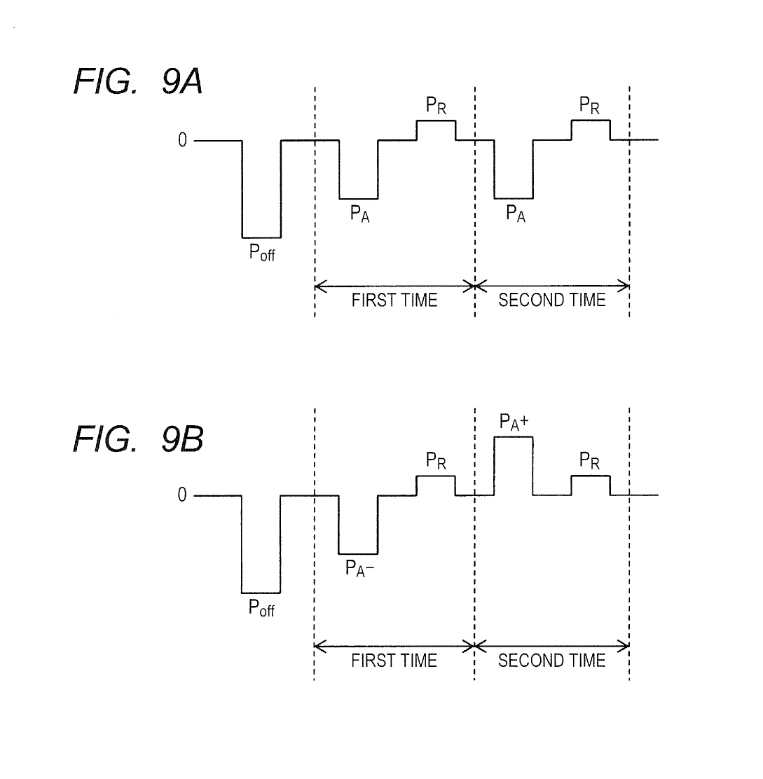

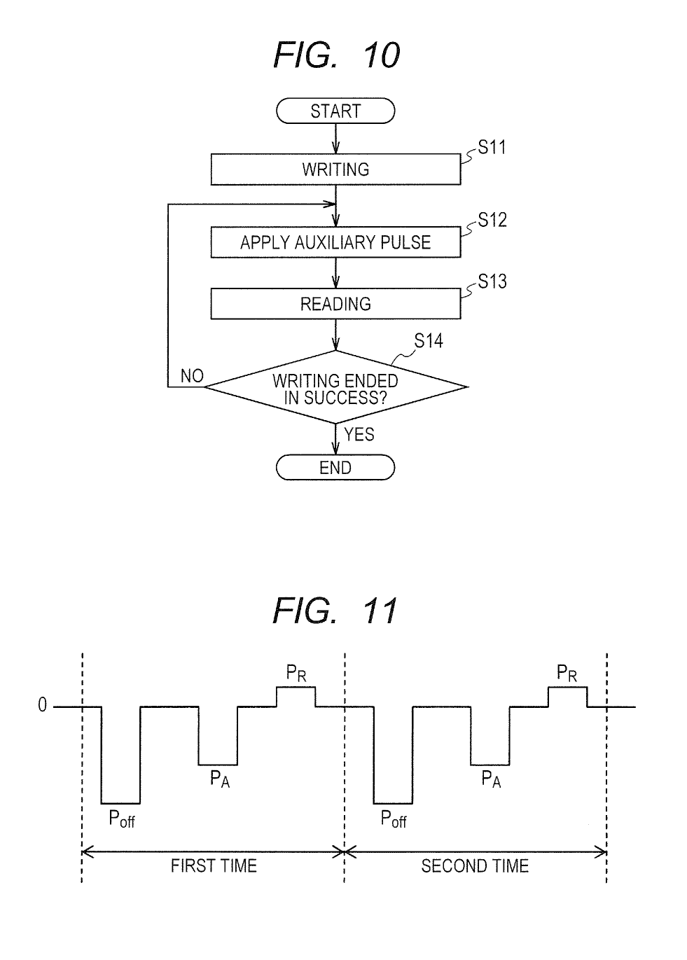

FIG. 9A and FIG. 9B each are a diagram illustrating one example of a waveform of a voltage to be applied when performing writing for switching the memory cell MC to the OFF state in the second embodiment. In addition, FIG. 10 is a flowchart illustrating one example of a procedure of writing for switching the memory cell MC to the OFF state in the second embodiment.

In the second embodiment, the technique of applying the auxiliary pulse P_{A} described in the first embodiment is combined with a general verify writing system. For example, as illustrated in FIG. 9A, first, the OFF write pulse P_{off} which is the main pulse is applied to the memory cell MC concerned to perform writing for switching the resistance change element VR to the OFF state (step S11 in FIG. 10). Then, the auxiliary pulse P_{A} is applied to the memory cell MC (S12) and thereafter a read pulse P_{R} for verification is applied so as to detect a current and thereby a resistance value of the resistance change element VR is read out (S13). Thereafter, whether writing has ended in success is decided on the basis of the read-out resistance value (S14). That is, when the resistance value meets a predetermined reference value (at least a predetermined value), it is decided that a first trial (verify processing) has ended in success and write processing is terminated.

On the other hand, when the resistance value of the resistance change element VR does not meet the predetermined reference value (less than the predetermined value), it is decided that the first trial has ended in failure and a second trial is performed by retuning to step S12. That is, the auxiliary pulse P_{A} is again applied (S12), thereafter the read pulse P_{R} is applied so as to read out the resistance value of the resistance change element VR (S13) and whether writing has ended in success is decided depending on whether the resistance value meets the predetermined reference value (S14). When writing still does not end in success, the above-mentioned trial is repetitively performed until it is decided that writing by application of the auxiliary pulse P_{A} has ended in success.

Incidentally, in order to avoid endless looping of the trials, in decision made in step S14, whether a repeated number of times has reached a predetermined upper limit repeated number of times which has been set in advance is decided in combination with the above-mentioned decision and when the repeated number of times has reached the upper limit repeated number of times (due to write errors and so forth), processing is terminated (the same also applies to other embodiments).

In addition, as illustrated in FIG. 9B, the polarity of the auxiliary pulse P_{A} may be changed for every trial. In addition, the number of the auxiliary pulses P_{A} to be applied in one trial is not limited to “1” as illustrated in the examples in FIG. 9A and FIG. 9B and the number may be “2” or more. In addition, in this case, the auxiliary pulses P_{A} of different polarities may be appropriately combined together. In addition, the waveform(s) of the main pulse P_{off} and/or the auxiliary pulse P_{A} in the second and succeeding trials is/are not limited to the waveform(s) of the pulse(s) in the first trial and the waveforms of pulses to be applied in the second and succeeding trials may be appropriately changed. For example, the amplitude of each pulse may be gradually increased and a pulse width may be gradually increased.

As described above, according to the ReRAM of the second embodiment, it is possible to more effectively improve the reliability of writing by combining the technique of applying the auxiliary pulse P_{A} described in the first embodiment with the general verify writing system.

### THIRD EMBODIMENT

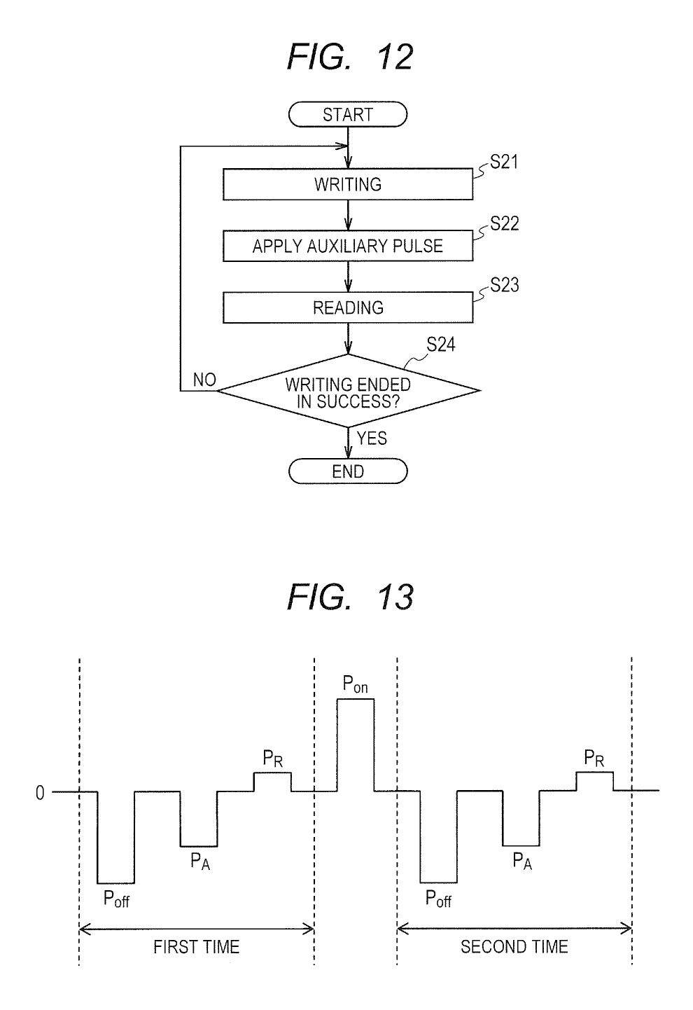

FIG. 11 is a diagram illustrating one example of a waveform of a voltage to be applied when performing writing for switching the memory cell MC to the OFF state in the third embodiment. In addition, FIG. 12 is a flowchart illustrating one example of a procedure of writing for switching the memory cell MC to the OFF state in the third embodiment.

Also in the third embodiment, the technique described in the first embodiment is combined with the general verify writing system as in the second embodiment. For example, as illustrated in FIG. 11, first, the write pulse P_{off} which is the main pulse is applied to the memory cell MC concerned and writing for switching the resistance change element VR to the OFF state is performed (step S21 in FIG. 12). Further, the auxiliary pulse P_{A} is applied to the memory cell MC (S22), thereafter the read pulse P_{R} for verification is applied so as to detect the current and thereby the resistance value of the resistance change element VR is read out (S23). Then, whether writing has ended in success is decided on the basis of the read-out resistance value (S24). That is, when the resistance value meets the predetermined reference value (at least the predetermined value), it is decided that the first trial has ended in success and write processing is terminated.

On the other hand, when the resistance value of the resistance change element VR does not meet the predetermined reference value (less than the predetermined value), it is decided that the first trial has ended in failure and the second trial is performed by returning to step S21 unlike the second embodiment. That is, the main pulse P_{off} is again applied and thereby writing for switching the resistance change element VR to the OFF state is performed (S21), the auxiliary pulse P_{A} is applied (S22), thereafter the read pulse P_{R} is applied so as to read out the resistance value of the resistance change element VR (S23) and whether writing has ended in success is decided depending on whether the resistance value meets the predetermined reference value (S24). When writing still does not end in success, the above-mentioned trial is repetitively performed until it is decided that writing performed by application of the main pulse P_{off} and the auxiliary pulse P_{A} ends in success or until the repeated number of times reaches the predetermined upper limit repeated number of times.

As described above, according to the ReRAM of the third embodiment, similarly to the case in the second embodiment, it is possible to more effectively improve the reliability of writing by combining the technique of applying the auxiliary pulse P_{A} described in the first embodiment with the general verify writing system.

### FOURTH EMBODIMENT

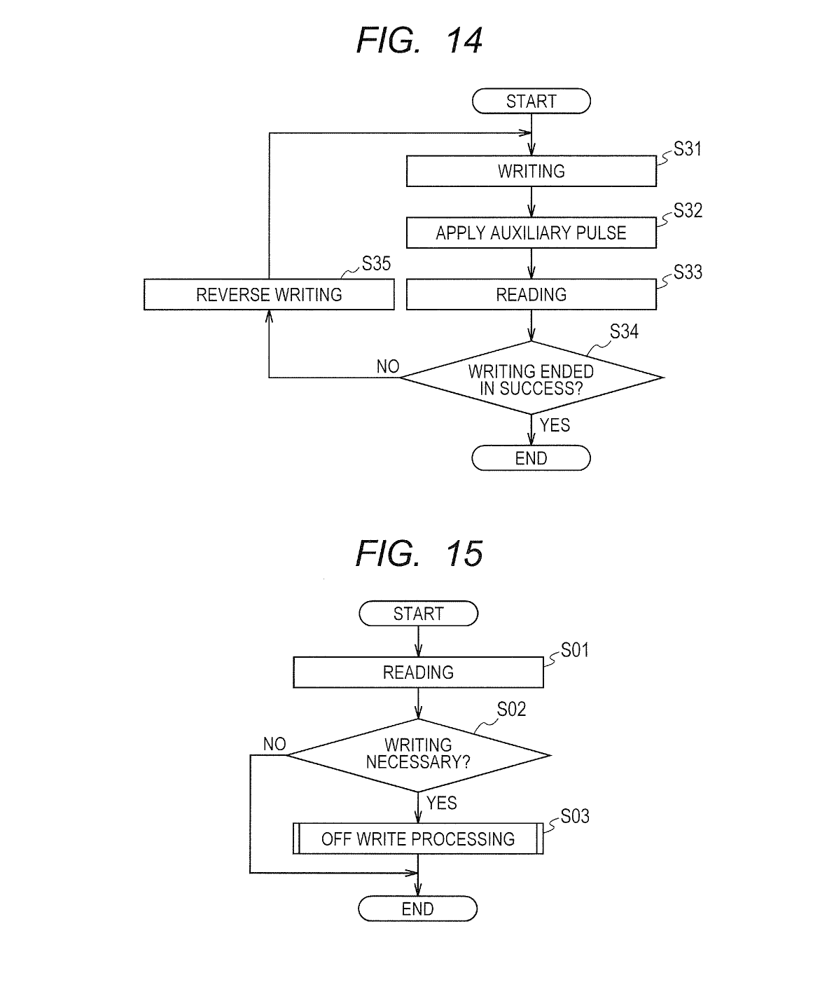

FIG. 13A and FIG. 13B each are a diagram illustrating one example of a waveform of a voltage to be applied when performing writing for switching the memory cell MC to the OFF state in the fourth embodiment. In addition, FIG. 14 is a flowchart illustrating one example of a procedure of writing for switching the memory cell MC to the OFF state in the fourth embodiment.

In the fourth embodiment, it is configured such that an ON write pulse Pₒₙ is applied to the memory cell MC concerned after the first trial has been performed and before the second trial is performed in the procedure described in the third embodiment. For example, as illustrated in FIG. 13, first, the OFF writ pulse P_{off} which is the main pulse is applied to the memory cell MC and writing for switching the resistance change element VR to the OFF state is performed (step S31 in FIG. 14). Then, the auxiliary pulse P_{A} is applied to the memory cell MC (S32), and thereafter the current is detected by applying the read pulse P_{R} for verification and thereby the resistance value of the resistance change element VR is read out (S33). Then, whether writing has ended in success is decided on the basis of the read-out resistance value (S34). That is, when the resistance value meets the predetermined reference value (at least the predetermined value), it is decided that the first trial has ended in success and write processing is terminated.

On the other hand, when the resistance value of the resistance change element VR does not meet the predetermined reference value (less than the predetermined value), it is decided that the first trial has ended in failure and the second trial is performed by returning to step S31 as in the case in the third embodiment. However, in the fourth embodiment, before the second trial is performed, the ON write pulse Pₒₙ of the reverse polarity is applied and reverse writing for switching the resistance change element VR to the ON state is performed (S35). Thereby, the pulse which is directed in a direction that the resistance change element VR is switched to the OFF state is repetitively applied and thereby it is possible to prevent accumulation of fatigue of the resistance change element VR and thereby it is possible to suppress a reduction in reliability of the resistance change element VR. Incidentally, the ON write pulse Pₒₙ may be made different from the OFF write pulse P_{off} in amplitude.

It is desirable to provide the step of deciding whether writing is necessary before performing writing, for example, in the first step S31 in order to avoid excessive writing as much as possible from the viewpoint of preventing accumulation of fatigue of the resistance change element VR. FIG. 15 is a flowchart illustrating another example of the procedure of writing for switching the memory cell MC to the OFF state in the fourth embodiment. Before performing a series of steps of OFF write processing for switching the resistance change element VR to the OFF state (S03) indicated in steps S31 to S35 in FIG. 14, first, the read pulse P_{R} is applied so as to read out the resistance value of the resistance change element VR (S01) and whether writing is necessary is decided on the basis of the read-out resistance value (S02). That is, when the resistance change element VR is in the OFF state where the resistance value is already at least the predetermined value, it is decided that writing is not necessary and processing is terminated, and only when the resistance change element VR is in the ON state, OFF write processing (S03) is performed.

Incidentally, it goes without saying that such advance decision processing as that illustrated in FIG. 15 is also applicable to OFF write processing illustrated in FIG. 10 and FIG. 12 and other OFF write processing.

As described above, according to the ReRAM of the fourth embodiment, accumulation of fatigue of the resistance change element VR is avoided by once performing ON writing for refreshing the resistance change element VR after the first trial has been performed and before the second trial is performed for OFF writing and thereby it is possible to suppress a reduction in reliability of the resistance change element VR. In addition, before performing writing, whether writing is necessary is decided in advance. Thereby, it is possible to avoid excessive writing to the greatest possible extent and thereby it is possible to suppress accumulation of the fatigue of the resistance change element VR.

### FIFTH EMBODIMENT

In the first to fourth embodiments, the procedure is such that the OFF write pulse P_{off} (the main pulse) is applied to the memory cell MC concerned only one time for every trial, the auxiliary pulse P_{A} is applied one or more time(s) for one-time application of the OFF write pulse P_{off} and thereafter the read pulse P_{R} for verification is applied. However, the procedure to be followed when writing is performed is not limited to the above-mentioned procedure. The main pulse may be applied a plurality of times for every trial and/or a verifying operation may be performed on the main pulse.

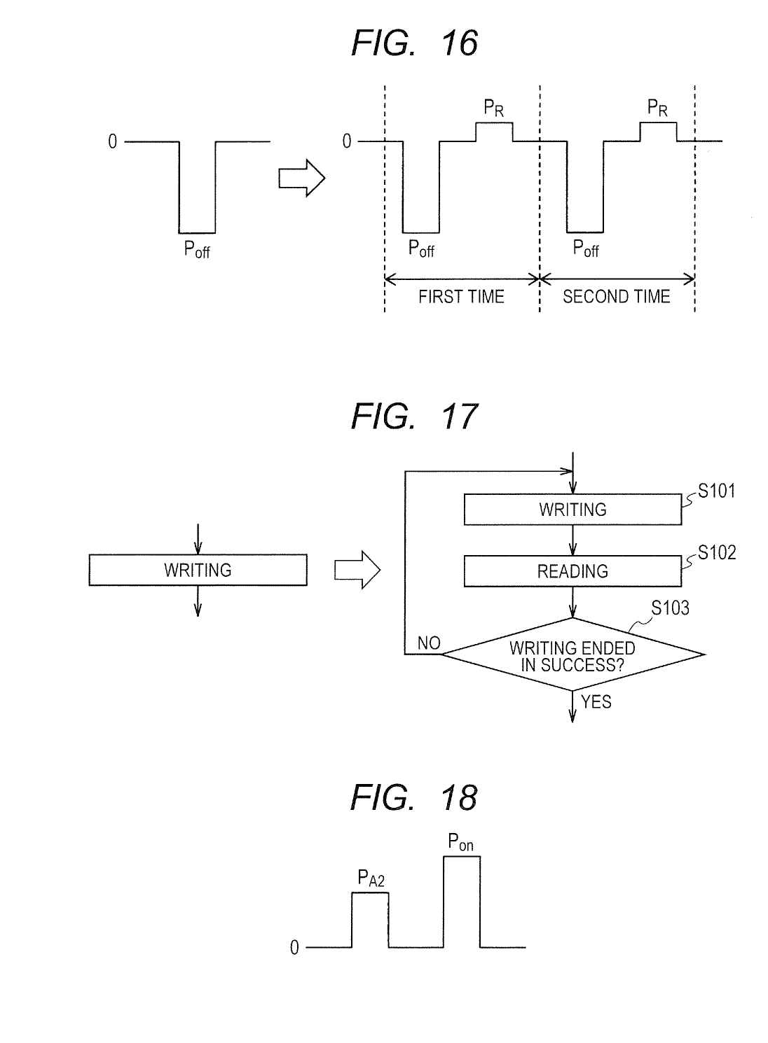

FIG. 16 is a diagram illustrating one example of a waveform of a voltage to be applied when the verifying operation is performed on the main pulse. In addition, FIG. 17 is a flow chart illustrating one example of a procedure of writing when the verifying operation is to be performed on the main pulse. In FIG. 16, the left-side drawing illustrates the single OFF write pulse P_{off} illustrated in FIG. 5 and FIG. 8 for the first embodiment, in FIG. 9 for the second embodiment, in FIG. 11 for the third embodiment and in FIG. 13 for the fourth embodiment and it is possible to replace this single OFF write pulse with the plurality of pulses configured by the OFF write pulse P_{off} and the read pulse P_{R} for verification as illustrated in the right-side drawing.

Likewise, in FIG. 17, the left-side drawing illustrates the writing step for applying the single OFF write pulse P_{off} in the flowcharts in FIG. 10 for the second embodiment, in FIG. 12 for the third embodiment and in FIG. 14 for the fourth embodiment and it is possible to replace this step with the plurality of steps as illustrated in the right-side drawing. That is, first, the OFF write pulse P_{off} is applied and writing for switching the resistance change element VR to the OFF state is performed (S101). Then, the read pulse P_{R} is applied and the resistance value of the resistance change element VR is read out (S102) and whether writing has ended in success is decided depending on whether the resistance value meets the predetermined reference value (S103). When writing does not end in success, the above-mentioned trial is repetitively performed by returning to step S101 until it is decided that writing by application of the OFF write pulse P_{off} has ended in success or the repeated number of times reaches the predetermined upper limit repeated number of times which has been set in advance.

As described above, according to the ReRAM of the fifth embodiment, the verifying operation is performed on the main pulse for every trial, when writing does not end in success, the main pulse is applied the plurality of times and thereby it is possible to effectively improve the reliability of writing.

Incidentally, when it has been determined that writing has ended in success in the step of deciding whether writing has ended in success (S103) or when the repeated number of times has reached the predetermined upper limit repeated number of times which has been set in advance, the flow shifts to the operation of applying the auxiliary pulse P_{A} as disclosed in the first to fourth embodiments. That is, it is possible to make compensation such that the write state is more stabilized by further applying the auxiliary pulse P_{A} after having switched to a state where writing would have been performed on the memory cell concerned MC. For example, in the cases in the first and second embodiments, after it has been determined that writing has ended in success in the above-mentioned decision on writing (S103), a decision is made by applying the auxiliary pulses P_{A} (P_{A+} and P_{A-}) and by applying the auxiliary pulses P_{A} (P_{A+} and P_{A-}) and the read pulse P_{R} for verification.

In addition, in the fifth embodiment, as illustrated in FIG. 16, first and second OFF write pulse applications are performed by using the same OFF write pulse P_{off}. However, the same pulse may not necessarily be applied repetitively and pulses and pulse arrays which are mutually different may be applied. For example, the OFF write pulse P_{off} which is to be secondarily applied may be made different from the OFF write pulse P_{off} which is to be firstly applied in voltage, current, pulse width, pulse polarity, number of times that the pulse is applied and so forth.

More specifically, it is also possible to repetitively perform verification so as to increase a success probability every time the trial is again performed by applying the OFF write pulse which has been increased in pulse width in the next writing to a bit line that writing has not been decided to end in success, in the next writing. There is obtained such a merit that it is possible to apply the necessary write pulse to each bit line in proper proportion by repetitively performing verification in this way. In addition, it is possible to once apply a pulse of the reverse polarity (that is, the pulse which is the same as the ON write pulse in polarity. This reverse polarity pulse may be different from the ON write pulse in voltage, pulse width and so forth) to the bit line that first writing has ended in failure and then to apply the OFF write pulse in the second and succeeding writing. It is possible to increase a success rate of OFF writing by performing writing in this way.

### SIXTH EMBODIMENT

As illustrated in FIG. 7 for the first embodiment, in each embodiment, it is important to apply the auxiliary pulse P_{A} to the resistance change element VR when the resistance change element VR is in the OFF state (the high-resistive state). Thereby, the electric field is effectively applied to the gap part between the metal layer and the conductive filament F1 and migration of oxygen occurs.

However, there are cases where migration of oxygen may also have an effect other than the effect of increasing the OFF resistance. That is, when, in the state illustrated in FIG. 7, oxygen accumulates much in the vicinity of an interface between the metal layer M1 and the resistance change layer VRL and then the resistance change element VR is switched to the ON state (the state in FIG. 6A), there is the possibility that the accumulated oxygen may deteriorate the conductive filament F1 which is located adjacent to the accumulated oxygen and the ON state retention characteristic may be deteriorated.

Therefore, when the resistance change element VR is in the OFF state (the state in FIG. 6A), a voltage (however, the voltage which is lower than a voltage which is necessary to switch the resistance change element VR to the ON state) which works in a direction that the metal layer M2 side is made positive and the resistance change element VR is switched to the ON state is applied as the auxiliary pulse so as to expel, in advance, oxygen accumulated in the vicinity of the interface from the interface. Thereby, the state retention characteristic when the resistance change element VR has been switched to the ON state later is improved. In other words, when the resistance change element VR is in the ON state, the auxiliary pulse is applied to the resistance change element VR prior to performance of ON writing and thereby it is possible to improve the state retention characteristic when the resistance change element VR has been switched to the ON state.

FIG. 18 is a diagram illustrating one example of a waveform when the auxiliary pulse is applied to the resistance change element VR prior to performance of ON writing. As illustrated in FIG. 18, prior to application of the main pulse Pₒₙ which is to be applied in ON writing, an auxiliary pulse P_{A2} which is lower than the main pulse Pₒₙ in voltage is applied. Incidentally, the auxiliary pulse P_{A2} may be applied a plurality of times in order to sufficiently expel the oxygen accumulated in the vicinity of the interface between the metal layer M1 and the resistance change layer VRL. In addition, it is desirable to make the pulse width of the auxiliary pulse P_{A2} wider than that of the ON write pulse Pₒₙ. It is possible to use such a method of performing ON writing as described in the sixth embodiment by appropriately combing with methods of performing ON writing described in the first to fifth embodiments.

As described above, according to the ReRAM of the sixth embodiment, when the resistance change element VR is in the OFF state, the auxiliary pulse P_{AZ} which is lower than the main pulse Pₒₙ in voltage is applied prior to application of the main pulse Pₒₙ which is to be applied in ON writing and thereby it is possible to improve the state retention characteristic when the resistance change element VR has been switched to the ON state.

### SEVENTH EMBODIMENT

Although in the first to sixth embodiments, description has been made by taking the configuration that the memory cell MC which stores one-bit information is configured by one resistance change element VR and one selection transistor TR by way of example as illustrated in FIG. 2, it is possible to apply the techniques described in the respective embodiments also to the ReRAM of the so-called cross point type configuration.

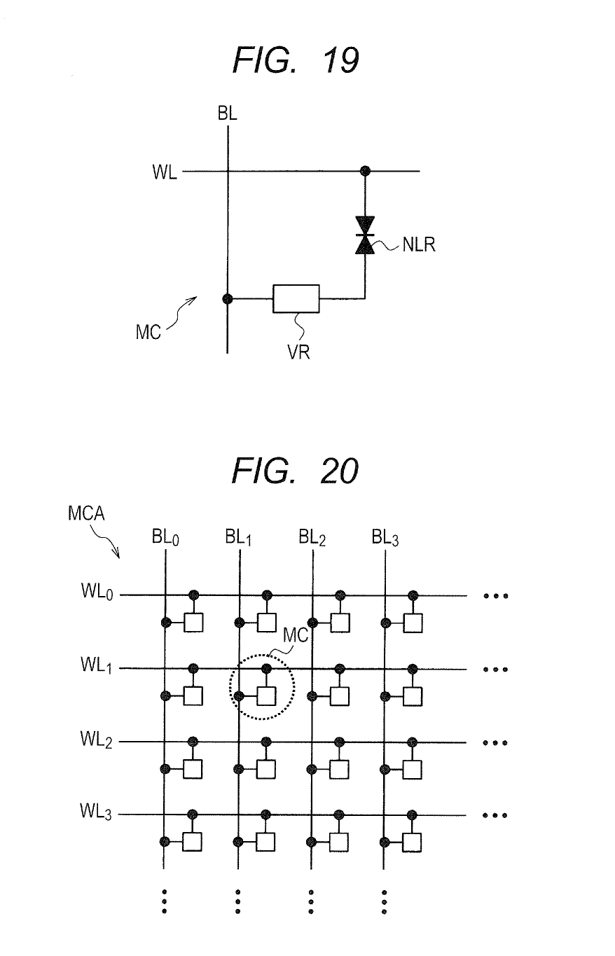

FIG. 19 is a schematic diagram illustrating one configurational example of the cross point type ReRAM. As illustrated in FIG. 19, the resistance change element VR is coupled with the word line WL and the bit line BL with no switch interposed. Incidentally, it is desirable that a nonlinear resistance element NLR be coupled in series with the resistance change element VR. Although there is no particular limitation on which metal layer is to be coupled with the bit line BL in the metal layer M1 and the metal layer M2 of the resistance change element VR, in the following, description will be made on the assumption that the metal layer M1 is coupled with the bit line BL.

FIG. 20 is a schematic diagram illustrating one configurational example of a memory array in the cross point type ReRAM. The memory array MCA may be configured by arranging the memory cells MC illustrated in FIG. 19 in a matrix. Although in the example of the memory cell array MCA illustrated in FIG. 20, the memory cell array has the configuration having the 16-bit memory capacity configured by the memory cells MC which are arranged in the matrix of four rows×four columns, it is possible to implement a larger memory capacity by appropriately increasing the numbers of the rows and the columns of the array.

The respective memory cells MC are each coupled to each node between each of the word lines WL₀ to WL₃ and each of the bit lines BL₀ to BL₃. Then, all of the word lines WL₀ to WL₃ and all of the bit lines BL₀ to BL₃ are coupled to the not illustrated control circuits on the periphery of the memory cell array MCA. For example, the word lines WL₀ to WL₃ are coupled to the not illustrated word line control circuit on the left side of the memory cell array MCA in the drawing. In addition, the bit lines BL₀ to BL₃ are coupled to the not illustrated bit line control circuit on the upper side of the memory cell array MCA in the drawing.

Each of the control circuits performs writing by appropriately applying the voltage to the corresponding line, that is, the bit line BL or the word line WL and switching the desired memory cell MC to the high resistive state or the low resistive state. Otherwise, each of the control circuits performs reading by detecting the current which flows through the bit line BL or the word line and determining whether the desired memory cell MC is in the high resistive state or the low resistive state.

For example, in writing for switching the memory cell MC which is circled with the dotted line to the ON state, the word line WL₁ may be set to the high potential, the bit line BL₁ may be set to the zero potential and other word lines WL₀, WL₂ and WL₃ and other bit lines BL₀, BL₂ and BL₃ may be each set to a potential which is half of the high potential. In contrast, in writing for switching the memory cell MC which is circled with the dotted lines to the OFF state, the word line WL₁ may be set to the zero potential, the bit line BL₁ may be set to the high potential and the other word lines WL₀, WL₂ and WL₃ and other bit lines BL₀, BL₂ may be each set to the potential which is half of the high potential.

In addition, when performing reading by determining whether the memory cell MC which is circled with the dotted line is in the ON state or the OFF state, the bit line BL₁ may be set to the zero potential, the other bit lines BL₀, BL₂ and BL₃ and all of the word lines WL₀ to WL₃ may be each set to the high potential (however, sufficiently lower than that which is set when performing writing) and then the current which flows through the word line WL₁ may be detected.

Owing to the above-mentioned operations, the high potential is applied across only the memory cell MC which is coupled to the word line WL₁ and the bit line BL₁ and the potential corresponding to half of the high potential or the zero potential is applied to each of other memory cells MC. Thereby, writing or reading is performed only on the memory cell MC which is circled with the dotted line. The same also applies to writing or reading performed on other memory cells MC.

Incidentally, the nonlinear resistance element NLR included in the memory cell MC illustrated in FIG. 19 has such a characteristic that it is switched to the high resistive state when a potential difference between the both ends is small and is switched to the low resistive state when the potential difference between the both ends is large. Accordingly, it has a function of reducing the voltage to be applied to the resistance change element VR and thereby avoiding erroneous writing and erroneous reading in other memory cells MC which share the bit line BL₁ or the word line WL₁ with the memory cell which is circled with the dotted line in FIG. 20, that is, in the memory cells MC to each of which the voltage corresponding to half of the high potential may be possibly applied.

It is possible to apply the techniques described in the first to sixth embodiments even to such a cross point type ReRAM as mentioned above and it is possible to increase the OFF resistance and to improve the characteristics of the resistance change element VR by applying the auxiliary pulse which is weaker than the main pulse to the predetermined memory cell MC when the predetermined memory cell MC is the OFF state.

In the foregoing, the invention which has been made by the inventors and others of the present invention has been specifically described on the basis of the preferred embodiments. However, it goes without saying that the present invention is not limited to the above-mentioned embodiments and may be altered and modified in a variety of ways within the scope not deviating from the gist of the present invention.

1. A semiconductor memory, comprising:
a memory cell which includes a resistance change element and a selection transistor configured to control whether a potential difference between a bit line and a plate line is to be applied to the resistance change element or to be blocked; and
a control circuit configured to perform a first write processing of applying a first write pulse to the memory cell in order to switch a state of the memory cell to a first resistive state where a resistance value of the resistance change element is at least a first reference value and a second write processing of applying a second write pulse to the memory cell in order to switch the state of the memory cell to a second resistive state where the resistance value of the resistance change element is less than a second reference value,
wherein the control circuit performs the first write processing by applying a first auxiliary pulse, which is smaller than the first write pulse in voltage amplitude, one or more time(s) after having applied the first write pulse to the memory cell.

2. The semiconductor memory according to claim 1, wherein the control circuit applies a read pulse for a verify processing for reading out in which state, the first resistive state or the second resistive state, the resistance change element is retained to the memory cell after having applied the first auxiliary pulse to the memory cell, and
wherein, when the memory cell is not retained in the first resistive state as a result of an execution of the verify processing, applies again the first auxiliary pulse to the memory cell and thereafter performs the verify processing.

3. The semiconductor memory according to claim 1, wherein the control circuit applies a read pulse for a verify processing for reading out in which state, the first resistive state or the second resistive state, the resistance change element is retained to the memory cell after having applied the first auxiliary pulse to the memory cell, and
wherein, when the memory cell is not retained in the first resistive state as a result of an execution of the verify processing, applies the first auxiliary pulse to the memory cell after having applied the first write pulse to the memory cell again and thereafter performs the verify processing.

4. The semiconductor memory according to claim 1, wherein the control circuit applies a read pulse for a verify processing for reading out in which state, the first resistive state or the second resistive state, the resistance change element is retained to the memory cell after having applied the first auxiliary pulse to the memory cell, and
wherein, when the memory cell is not retained in the first resistive state as a result of an execution of the verify processing, applies the second write pulse to the memory cell, then applies the first auxiliary pulse to the memory cell after having applied the first write pulse again and thereafter performs the verify processing.

5. The semiconductor memory according to claim 1, wherein the first auxiliary pulse is the same as the first write pulse in polarity.

6. The semiconductor memory according to claim 1, wherein, in the first auxiliary pulse, a pulse which is reverse to the first write pulse in polarity is included.

7. The semiconductor memory according to claim 1, wherein the control circuit performs the second write processing by applying the second write pulse to the memory cell after having applied a second auxiliary pulse which is smaller than the second write pulse in voltage amplitude to the memory cell one or more time(s).

8. The semiconductor memory according to claim 1, wherein the semiconductor memory comprises a bipolar type Resistive Random Access Memory (ReRAM).

9. A semiconductor memory, comprising:
a memory cell which includes a resistance change element and a selection transistor configured to control whether a potential difference between a bit line and a plate line is to be applied to the resistance change element or to be blocked; and
a control circuit configured to perform a first write processing of applying a first write pulse to the memory cell in order to switch a state of the memory cell to a first resistive state where a resistance value of the resistance change element is at least a first reference value and a second write processing of applying a second write pulse to the memory cell in order to switch the state of the memory cell to a second resistive state where the resistance value of the resistance change element is less than a second reference value,
wherein the first write processing includes:
(a) applying the first write pulse to the memory cell;
(b) after (a), applying a first read pulse for deciding in which state the resistance change element is retained, the first resistive state or the second resistive state;
(c) after (b), again performing (a) and (b) on the memory cell, when the memory cell is not retained in the first resistive state; and
(d) after (b), applying a first auxiliary pulse which is smaller than the first write pulse in voltage amplitude one or more time(s) when the memory cell is retained in the first resistive state or when (c) has been repetitively performed until reaching a predetermined upper limit repeated number of times which has been set in advance.

10. The semiconductor memory according to claim 9, wherein the first write pulse which is applied again in (c) is a pulse which is the same as the first write pulse applied in (a).

11. The semiconductor device according to claim 9, wherein the first write pulse which is applied again in (c) includes a pulse or a pulse train which is different from the first write pulse applied in (a).

12. The semiconductor memory according to claim 9, wherein the first write processing further includes:
after (d), applying a second read pulse for deciding in which state, the first resistive state or the second resistive state, the resistance change element is retained to the memory cell.

13. The semiconductor memory according to claim 1, wherein the resistance change element is coupled to the plate line at one terminal and is coupled to the bit line at an other terminal via the selection transistor.

14. The semiconductor memory according to claim 13, wherein a gate of the selection transistor is coupled to a word line.

15. The semiconductor memory according to claim 1, wherein a polarity of a voltage applied to the resistance change element is configured to be switched depending on which one of potentials of the bit line and the plate line is set higher.

16. The semiconductor memory according to claim 1, wherein to switch the resistance change element of the memory cell to the first resistive state, a voltage which is higher than a voltage applied to a plate line side is applied to a bit line side of the resistance change element.

17. The semiconductor memory according to claim 9, wherein the resistance change element is coupled to the plate line at one terminal and is coupled to the bit line at an other terminal via the selection transistor.

18. The semiconductor memory according to claim 17, wherein a gate of the selection transistor is coupled to a word line.

19. The semiconductor memory according to claim 9, wherein a polarity of a voltage applied to the resistance change element is configured to be switched depending on which one of potentials of the bit line and the plate line is set higher.

20. The semiconductor memory according to claim 9, wherein to switch the resistance change element of the memory cell to the first resistive state, a voltage which is higher than a voltage applied to a plate line side is applied to a bit line side of the resistance change element.
